(19) United States
(12) Patent Application Publication
(10) Pub. No.: US 2004/0169276 A1
(43) Pub. Date: Sep. 2, 2004

(54) Method of packaging a semiconductor chip

(76) Inventor: Loon Lee Tan, Kallang Way (SG)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 10/478,656

(22) PCT Filed: May 28, 2001
(86) PCT No.: PCT/SG01/00107

(51) Int. Cl. H01L 23/48

(52) U.S. Cl. 257/737

(57) ABSTRACT

A method of packaging a semiconductor chip (2) includes forming metallic bumps (5) on electrical contact areas (3) on an active surface (4) of a semiconductor chip (2). The semiconductor chip (2) is inserted into a mold (18, 19) and an electrically insulating material (6) is molded across the active surface (4) between the metallic bumps (5). The chip (2) is then removed from the mold (18, 19).

The invention relates to a method of packaging a semiconductor chip.

The term “flip chip” is used to refer to any semiconductor chip (or die) in which solder bumps are formed on bond pads of the chip and the bond pads are located on the active surface of the chip. When the flip chip is attached to a substrate, such as a printed circuit board (PCB), the solder bumps form the electrical contacts between the die pads and the electrical contact areas on the substrate, and also provide the mechanical connection between the chip and the substrate. The flip chip is normally attached to the substrate by using a process known as re-flow which involves heating the solder bumps to melt the solder bumps and then allowing the melted solder bumps to cool so that the solder electrically and mechanically connects the die pads to the contact areas on the substrate.

Conventionally, after a flip chip has been attached to a PCB by re-flow, there will be an air gap between the active surface of the chip and the surface of the PCB. It is necessary to fill the air gap to seal the active surface of the PCB to minimise the possibility of contamination and damage during use. This is normally a relatively slow process as it requires an underfill material to be injected between the PCB and the active surface of the chip, and the gap between the active surface and the surface of the PCB is normally relatively small. Typically, of the order of 0.2 mm to 0.4 mm.

Due to the number of the bumps on a typical die, which may be in excess of hundred, the relatively small gap between the active surface of the die and the PCB and that the die pads on the die, and therefore the solder bumps, are relatively close together, it is also difficult to ensure that the entire air gap between the active surface of the die and the surface of the PCB is properly underfilled and that there are no air gaps or bubbles in the underfill.

In accordance with a first aspect of the present invention, there is provided a method of packaging a semiconductor chip comprising forming metallic bumps on electrical contact areas on an active surface of a semiconductor chip, inserting the semiconductor chip in a mold, molding an electrically insulating material across the active surface of the chip between the metallic bumps, and removing the chip from the mold.

An advantage of the invention is that by molding a material between the bumps and across the active surface of the chip prior to attachment of the chip to a substrate, it is possible to use conventional semiconductor chip molding techniques and materials to cover the active surface of the semiconductor chip.

Preferably, the molding is performed such that the molding material does not cover the metallic bumps. Typically, a portion of the metallic bumps is still exposed after molding.

Typically, a layer of material, such as a film of material, for example, an adhesive film, may be used to prevent the electrically insulating material covering the metallic bumps during molding.

Typically, a layer of material, such as a film of material, for example, an adhesive film may also be used to cover the non-active surface of the semiconductor chip during molding.

In one example of the invention, the electrically insulating material is molded onto the active surface of the chip prior to singulation of the chips from the wafer on which they are formed.

In an alternative example of the invention, the electrically insulating material is molded onto the active surface after singulation.

Preferably, the electrically insulating material is molded onto the active surface after a metallic bump height levelling process.

In accordance with a second aspect of the present invention, there is provided a semiconductor device comprising a semiconductor chip having an active surface and electrical contact areas located on the active surface, a metallic bump formed on each electrical contact area and an electrically insulating material covering the active surface between the metallic bumps, a portion of each metallic bump not being covered by the electrically insulating material.

Preferably, the electrically insulating material is a molding compound, such as an epoxy resin.

In accordance with a third aspect of the present invention, there is provided a method of attaching a flip chip to a substrate, the method comprising molding an electrically insulating material onto the active surface of the flip chip between metallic bumps such that a portion of each metallic bump is not covered by the molding material, and subsequently attaching the metallic bumps to electrical contact areas on the substrate.

Typically, the substrate is a laminated substrate, such as a substrate having an electrically insulating core material, for example, a glass fibre/epoxy resin core material.

Preferably, the metallic bumps are connected to the electrical contact areas on the substrate by heating the metallic bumps to cause the metallic bumps to melt and subsequently cooling the metallic bumps so that the metallic bumps attaches to the electrical contact areas on the substrate.

Typically, the metallic bumps are solder bumps.

An example of a semiconductor device in accordance with the invention will now be described with reference to the accompanying drawings, in which:

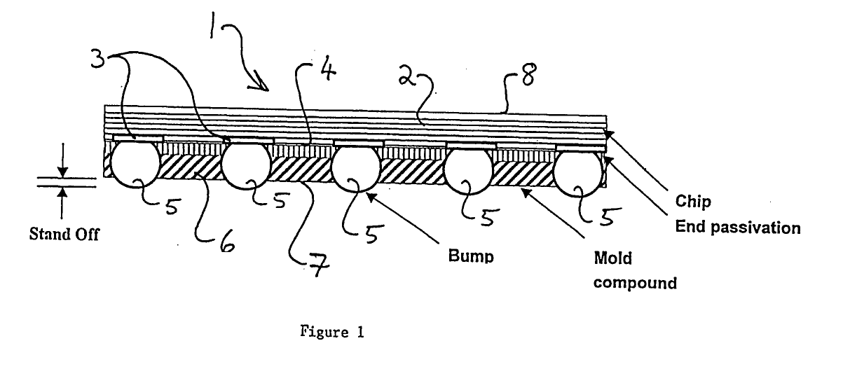

FIG. 1 is a cross-sectional view of an encapsulated flip chip;

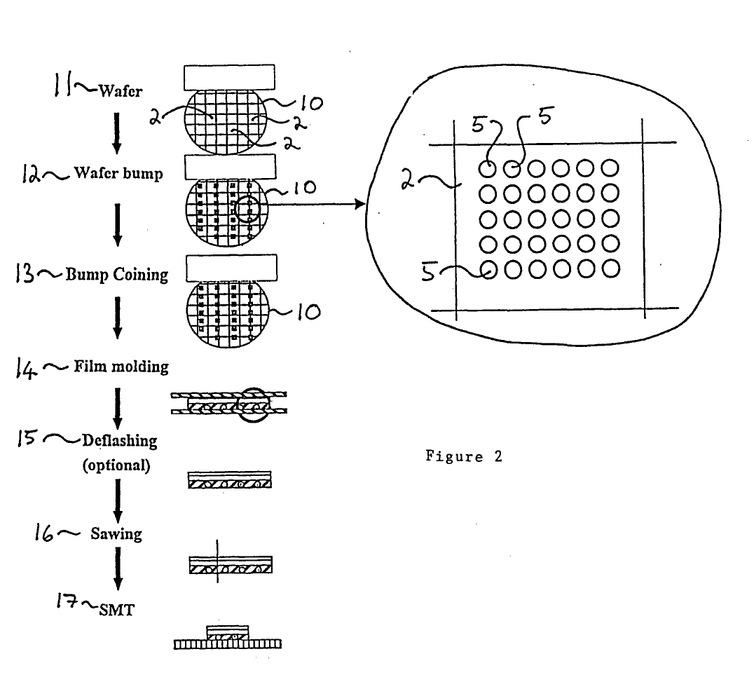

FIG. 2 is a flow diagram showing a first example of a process for packaging the flip chip shown in FIG. 1;

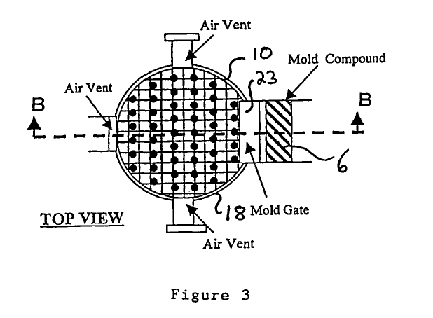

FIG. 3 is a plan view showing a molding step during the process of FIG. 2;

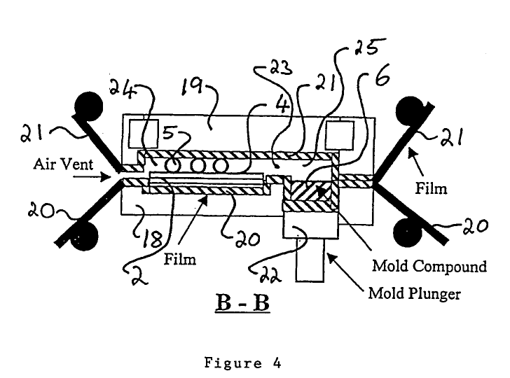

FIG. 4 is a cross-sectional view through the line BB of FIG. 3;

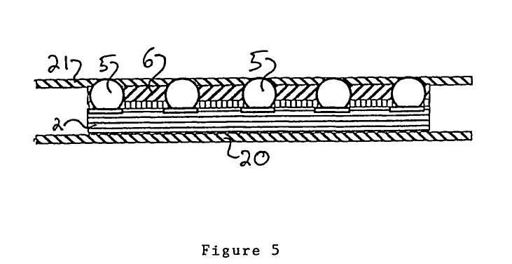

FIG. 5 is an enlarged schematic view of the flip chip after molding but before removal from a mold;

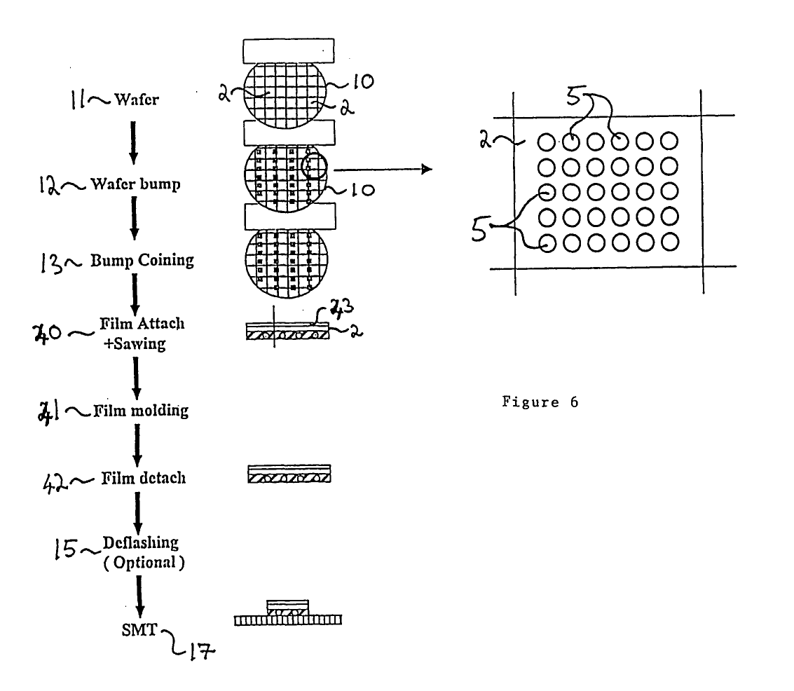

FIG. 6 is a flow diagram showing a second example of a process for packaging the flip chip shown in FIG. 1;

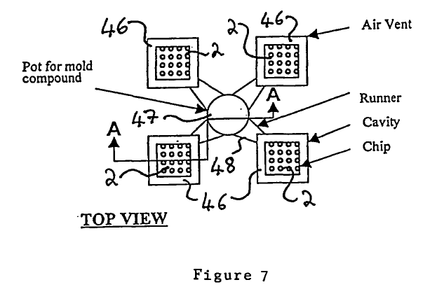

FIG. 7 is a plan view showing a molding step in the process shown in FIG. 6;

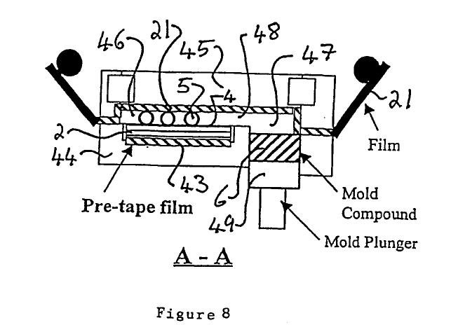

FIG. 8 is a cross-sectional view through the line AA of FIG. 7; and

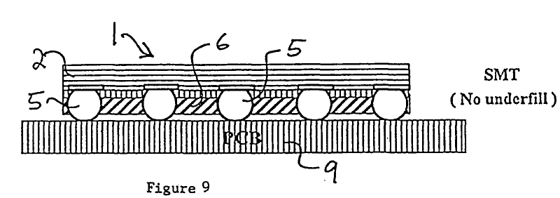

FIG. 9 is a cross-sectional view showing the encapsulated flip chip of FIG. 1 mounted on a substrate.

FIG. 1 shows a semiconductor flip chip package 1 according to the invention. The package 1 includes a semiconductor chip 2 which has a number of bond pads 3 located on an active surface 4 of the chip 2. Formed on each of the bond pads 3 is a solder bump 5 and molding compound 6, such as an epoxy resin, is molded onto the active surface 4 between the solder bumps 5 to cover and protect the active surface 4 of the chip 2. As shown in FIG. 1, surface 7 of the molding compound 6 is below the level of the solder bumps 5 so that the molding compound 6 does not cover the solder bumps 5. This is important to ensure that at least a portion of each solder bump 5 remains exposed to permit the solder bumps 5 to be used to mechanically and electrically connect the package 1 to a substrate.

In order to mold the molding compound 6 onto the active surface 4, a number of suitable molding techniques are possible. FIGS. 2 to 4 show a first molding process in which the molding compound is molded onto the active surface 4 before singulation of chip 2 from the wafer on which the chip 2 is formed. FIGS. 5 to 7 show a second molding technique in which the molding compound is molded onto the active surface 4 of the chip 2 after singulation of the chip 2 from the wafer on which the chip 2 is formed.

FIG. 2 is a flow diagram showing a first process for manufacturing the flip chip package 1 from the wafer stage through to surface mounting of the finished package on a substrate, such as a PCB. In the process, a wafer 10 including a number of semiconductor chips 2 is fabricated 11. Solder bumps 5 are then formed 12 on each bond pad of each conductor chip 2. After forming the bumps 5, the bumps 5 may vary in size. Therefore, a bump coining process 13 is performed to level out the bumps 5 so that they are all approximately the same height.

After bump coining 13, the wafer 10 undergoes a film molding process 14 which is shown in more detail in FIGS. 3 and 4. FIG. 3 shows that the wafer 10 is positioned in a lower mold half 18. The wafer 10 is positioned in the lower mold half 18 so that the active surface 4 and bumps 5 are directed upwards towards an upper half 19 (see FIG. 4). A layer of thin film 20 is used to line the lower mold half 18 and is interposed between the non-active surface. 8 of the chip 2 on the wafer 10 and the lower mold half 18. Another thin film 21 is used to line the upper mold half 19 and is interposed between the mold bumps 5 and the upper mold half 19. The mold compound 6 is located in a mold compound pot 25 in the lower mold half 18 above a mold compound plunger 22. When the mold halves 18, 19 are heated, the mold compound 6 melts and the mold plunger 22 is moved upwards to force the melted mold compound 6 through a mold gate 23 and into a main mold cavity 24 so that the mold compound 6 fills the mold cavity 24 and covers the active surface 4 of the chip 2 between the bumps 5.

The presence of the film 20 minimises the mold compound 6 covering the non-active surface 8 of the chip 2 and the film 21 prevents the mold compound 6 from covering the solder bumps 5. The film 21 compresses slightly where the bumps 5 contact the film 21 when the mold halves 18, 19 are closed, due to the pressure between the solder bumps and the mold half 19. The compression of the film 21 around the solder bumps 5 causes the level of the molding compound 6 to be below the level of the solder bumps 5. This is shown in FIG. 5 which is an enlarged view of a chip 2 after molding but before removal of the wafer 10 from the mold halves 18, 19.

After the film molding process 14, an optional deflashing process 15 can be performed on the wafer 10 to remove unwanted flashing of the mold compound on the wafer 10 prior to carrying out a sawing process 16 to singulate the wafer 10 to form the individual flip chip packages 1. After the sawing process 16, a surface mount process 17 can be performed to mount the package 1 on a laminated substrate, such as a PCB 9, as shown in FIG. 9. The mounting of the package 1 to the PCB 9 can be performed using a conventional reflow technique which involves heating the solder bumps 5 so that they melt and stick to corresponding contact pads on the PCB 9.

FIG. 6 shows a flow diagram illustrating a second process for manufacturing the package 1. The second process is similar to the first process, except that the wafer 10 is singulated before the film molding process. As shown in FIG. 6, after the bump coining process 13, the wafer 10 undergoes a film attach and sawing process 20. This involves the wafer 10 being sawed into separate chips 2 and then attaching a thin adhesive film 23 to the non-active surface 8 of each chip 2. The chips 2 then undergo a film molding process 21 which is shown in more detail in FIGS. 7 and 8. As shown in FIGS. 7 and 8, a mold comprises a lower mold half 44 and an upper mold half 45. The mold includes a number of mold cavities 46 which each accept one of the singulated chips 2. Each of the mold cavities 46 is connected to a mold compound pot 47 by a runner 48. The film 21 is again used to line the upper mold half 45 and the thin film 21 performs the same purpose as the film 21 used to line the upper mold half 19 shown in FIG. 4. That is, to ensure that the solder bumps 5 are not covered by the mold compound during molding and that the level of the molding compound is below the level of the bumps 5.

During molding, the mold halves 44, 45 are heated to cause the mold compound 6 in the pot 47 to melt. Plunger 49 then pushes the melted mold compound 6 through the runners 48 to the mold cavities 46 so that the mold compound is molded onto the active surface 4 of the chip 2 and around the solder bumps 5. The film 43 helps to minimise flashing of the mold compound 6 onto the non-active surface 8 of the chip 2.

After the film molding process 41 has been completed, the film 43 is detached 42 from the non-active surface 8 of the chips 2 and the chips may undergo an optional deflashing process 15.

After the optional deflashing process 15, or the film detach process 42, if the deflashing process is not used, the molded flip chip packages 1 are ready to be surface mounted 17 on a laminated substrate, such as the PCB 9 using conventional reflow techniques to attach the package 1 to the PCB 9, as shown in FIG. 9.

The invention has the advantage that it uses conventional molding techniques to cover the active surface 4 of a flip chip 2 and does not require an underfill process to be used after mounting of the flip chip package 1 on the substrate, such as a PCB 9. In addition, the presence of the molding compound 6 may help to reduce cracking of the solder bump/bond pad interface during solder reflow. Therefore, the invention mitigates the disadvantages associated with conventional underfill techniques.

1. A method of packaging a semiconductor flip chip comprising forming metallic bumps on electrical contact areas on an active surface of a semiconductor chip, inserting the semiconductor chip into a mold, molding an electrically insulating material across the active surface between the metallic bumps, and removing the chip from the mold.

2. A method according to claim 1, wherein the molding is performed such that the molding material does not cover the metallic bumps.

3. A method according to claim 2, wherein a portion of the metallic bumps is still exposed after molding.

4. A method according to claim 2 or claim 3, wherein a first layer of material is placed over the metallic bumps during molding.

5. A method according to any of the preceding claims, wherein a second layer of material is placed over the non-active surface of the semiconductor chip during molding.

6. A method according to any of the preceding claims, wherein the electrically insulating material is molded onto the active surface of the chip prior to separation of the chip from a wafer on which the chip is formed.

7. A method according to any of claims 1 to 5, wherein the electrically insulating material is molded onto the active surface of the chip after separation of the chip from a wafer on which the chip is formed.

8. A method according to any of the preceding claims, wherein the electrically insulating material is molded onto the active surface after a metallic bump height leveling process.

9. A semiconductor flip chip comprising a semiconductor chip having an active surface and electrical contact areas located on the active surface, a metallic bump formed on each electrical contact area and an electrically insulating material covering the active surface between the metallic bumps for attachment to an electrical contact area on a substrate, a portion of each metallic bump not being covered by the electrically insulating material.

10. A semiconductor flip chip according to claim 9, wherein the electrically insulating material is a molding compound.

11. A semiconductor flip chip according to claim 10, wherein the molding compound is an epoxy resin.

12. A semiconductor flip chip according to any of claims 9 to 11, wherein the metallic bumps are solder bumps.

13. A method of attaching a flip chip to a substrate, the method comprising molding an electrically insulating material onto an active surface of the flip chip between metallic bumps formed on first electrical contact areas on the active surface such that a portion of each metallic bump is not covered by the molding material, and subsequently attaching the metallic bumps to second electrical contact areas on the substrate.

14. A method according to claim 13, wherein the substrate is a laminated substrate.

15. A method according to claim 13 or claim 14, wherein the metallic bumps are connected to the second electrical contact areas by heating the metallic bumps to cause the metallic bumps to melt and subsequently cooling the metallic bumps so that the metallic bumps attach to the second electrical contact areas.
